(19) United States
(12) Patent Application Publication
(10) Pub. No.: US 2026/0215109 A1
(43) Pub. Date: Jul. 23, 2026

(54) ELECTRONIC DEVICE

(71) Applicant: Samsung Display Co., Ltd., Yongin-Si (KR)

(72) Inventor: HYEYOUNG KIM, Yongin-si (KR)

(21) Appl. No.: 19/362,039

(22) Filed: Oct. 17, 2025

(30) Foreign Application Priority Data
Jan. 22, 2025 (KR) 10-2025-0009162

(51) Int. Cl. H10K 59/131; H10K 59/95

(52) U.S. Cl. CPC H10K 59/131; H10K 59/95

(57) ABSTRACT

Provided is an electronic device including a display panel, an electronic component electrically connected to the display panel, and a conductive adhesive layer electrically connecting the display panel and the electronic component. The display panel includes a pixel, a signal line electrically connected to the pixel, and a signal pad electrically connected to the signal line, and the signal pad includes a first pad, and a second pad spaced apart from the first pad. The first pad and the second pad transmit the same data signal to the signal line.

### CROSS-REFERENCE TO RELATED APPLICATIONS

This U.S. non-provisional patent application claims priority under 35 U.S.C. § 119 to Korean Patent Application No. 10-2025-0009162, filed on January 22, 2025, the entire contents of which are hereby incorporated by reference.

### BACKGROUND

The present disclosure herein relates to an electronic device, and more particularly, to an electronic device including electronic components electrically connected.

Various electronic devices used in multimedia devices such as a television, a mobile phone, a tablet computer, a navigation unit, a game console, etc. may display images and detect external inputs. The electronic devices may include a plurality of electronic components, such as a display panel, a driving chip package, and a circuit board, and the electronic components are electrically connected in various manners.

When contact failure is caused or a short circuit occurs in the electrically connected electronic components, a vertical line defect that a stain or a dark spot is visible along the vertical direction may occur in a display region of an electronic device.

### SUMMARY

The present disclosure provides an electronic device with improved electrical bonding reliability.

The present disclosure also provides an electronic device in which a vertical line defect does not occur even when a short occurs between pads.

An embodiment of the inventive concept provides an electronic device including: a display panel; an electronic component electrically connected to the display panel; and a conductive adhesive layer electrically connecting the display panel and the electronic component, wherein the display panel includes a pixel, a signal line electrically connected to the pixel, and a signal pad electrically connected to the signal line, the signal pad includes a first pad, and a second pad spaced apart from the first pad, and the first pad and the second pad transmit a same data signal to the signal line

In an embodiment, the electronic component may include a driver chip package, and the driver chip package may include an input bump configured to receive a first signal from the outside, and an output bump configured to provide a second signal generated according to the first signal.

In an embodiment, the output bump may include: a first bump electrically connected to the first pad; and a second bump electrically connected to the second pad.

In an embodiment, the driver chip package further may include a driver chip including a first output terminal and a package substrate, and the first output terminal may provide the second signal to the first bump and the second bump.

In an embodiment, the driver chip package may further include a driver chip including a first output terminal and a package substrate, and the package substrate may include a first switching element configured to control the second signal of the first bump, and a second switching element configured to control the second signal of the second bump.

In an embodiment, the conductive adhesive layer may include an adhesive layer and a plurality of conductive balls disposed in the adhesive layer, and when some of the plurality of conductive balls electrically connect the first bump and the second bump, the first switching element or the second switching element may be turned off.

In an embodiment, the output bump may be provided in plurality, the plurality of output bumps may include a first output bump and a second output bump, and the first output bump may output a first data signal, and the second output bump may output a second data signal.

In an embodiment, the conductive adhesive layer may include an adhesive layer and a plurality of conductive balls disposed in the adhesive layer, and when some of the plurality of conductive balls electrically connect the first bump of the first output bump and the first bump of the second output bump, the first bump of the first output bump may not output the first data signal and the first bump of the second output bump may output the second data signal.

In an embodiment, the signal pad may be provided in plurality, the plurality of signal pads may include a first signal pad and a second signal pad, the first signal pad and the second signal pad may be disposed in a same row, and the first signal pad may receive a first data signal, and the second signal pad may receive a second data signal.

In an embodiment, the conductive adhesive layer may include an adhesive layer and a plurality of conductive balls disposed in the adhesive layer, and when some of the plurality of conductive balls electrically connect the first pad of the first signal pad and the first pad of the second signal pad, the first pad of the first signal pad may not receive the first data signal and the first pad of the second signal pad may receive the second data signal.

In an embodiment, the first pad and the second pad may respectively include a first conductive pattern electrically connected to a terminal portion of the signal line, and a second conductive pattern disposed on the first conductive pattern.

In an embodiment, the signal pad may extend in a first direction, the display panel may further include a dummy pad spaced apart from the signal pad in a second direction crossing the first direction, a length of the first pad in the first direction may be smaller than a length of the dummy pad in the first direction, and a length of the second pad in the first direction may be smaller than a length of the dummy pad in the first direction.

In an embodiment, the signal pad may extend in the first direction, the display panel may further include a dummy pad spaced apart from the signal pad in the second direction crossing the first direction, a length of the first pad in the second direction may be smaller than a length of the dummy pad in the second direction, and a length of the second pad in the second direction may be smaller than a length of the dummy pad in the second direction.

In an embodiment, the signal pad may further include a third pad which is spaced apart from the first pad and the second pad, and the fist pad, the second pad and the third pad may transmit the same data signal to the same signal line.

In an embodiment of the inventive concept, an electronic device includes: a first electronic component including an input pad and an output pad spaced apart from the input pad; a second electronic component including an input bump configured to receive a first signal from the input pad, and an output bump configured to provide a second signal generated from the output pad according to the first signal; and a conductive adhesive layer electrically connecting the first electronic component and the second electronic component, wherein the output bump includes a first bump and a second bump spaced apart from the first bump, and the first bump and the second bump output the same data signal to the first electronic component.

In an embodiment, the output pad may include: a first pad electrically connected to the first bump; and a second pad electrically connected to the second bump.

In an embodiment, the second electronic component may further include a driver chip including a first output terminal and a package substrate, and the first output terminal may provide the second signal to the first bump and the second bump.

In an embodiment, the package substrate may include: a first switching element configured to control the second signal of the first bump; and a second switching element configured to control the second signal of the second bump.

In an embodiment, the conductive adhesive layer may include an adhesive layer and a plurality of conductive balls disposed in the adhesive layer, and, when some of the plurality of conductive balls electrically connect the first bump and the second bump, the first switching element or the second switching element may be turned off.

In an embodiment, the second electronic component may further include a dummy bump spaced apart from the output bump, an area of the first bump may be smaller than an area of the dummy bump, and an area of the second bump may be smaller than an area of the dummy bump.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of an electronic device according to an embodiment of the inventive concept;

FIG. 2 is a schematic view of electronic devices according to embodiments of the inventive concept;

FIG. 3 is a combined perspective view of an electronic device according to an embodiment of the inventive concept;

FIG. 4 is an exploded perspective view of an electronic device according to an embodiment of the inventive concept;

FIG. 5 is a cross-sectional view of a display device according to an embodiment of the inventive concept;

FIG. 6 is a plan view of a display panel according to an embodiment of the inventive concept;

FIG. 7 is a cross-sectional view of a display panel according to an embodiment of the inventive concept;

FIG. 8 is an exploded perspective view of a bonding region according to an embodiment of the inventive concept;

FIG. 9A is a plan view illustrating an arrangement of chip bumps on a driver chip according to an embodiment of the inventive concept;

FIG. 9B is a plan view of a first pad region of a display panel according to an embodiment of the inventive concept;

FIG. 9C is an enlarged plan view of a first signal pad according to an embodiment of the inventive concept;

FIG. 10 is a cross-sectional schematic view of a bonding region according to an embodiment of the inventive concept;

FIG. 11 is a plan view illustrating a state in which one part of pads in first pad region according to an embodiment of the inventive concept is floated;

FIG. 12 is a cross-sectional schematic view of a bonding region illustrating a state in which one part of pads according to an embodiment of the inventive concept is floated; and

FIGS. 13A and 13B are respectively plan views of first pad regions of display panels according to other embodiments of the inventive concept.

### DETAILED DESCRIPTION

In this specification, it will be understood that when an element (or a region, a layer, a portion, or the like) is referred to as being "on", "connected to" or "coupled to" another element, it may be directly disposed on/connected to/coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term "and/or" includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

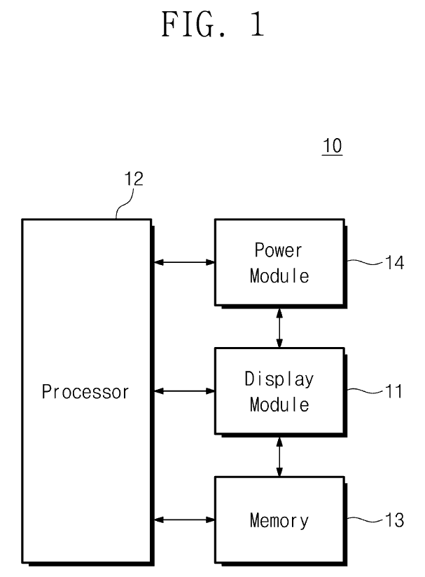

FIG. 1 is a block diagram of an electronic device 10 according to an embodiment.

Referring to FIG. 1, the electronic device 10 according to an embodiment may include a display module 11, a processor 12, a memory 13, and a power module 14.

The display module 11 may display images. The images may include not only a dynamic image but also a static image.

The processor 12 may include at least one of a central processing unit (CPU), an application processor (AP), a graphic processing unit (GPU), a communication processor (CP), an image signal processor (ISP), or a controller. The processor 12 may control an operation of the display module 11.

The memory 13 may store data information necessary for an operation of the processor 12 or the display module 11. When the processor 12 executes an application stored in the memory 13, image data signals and/or input control signals are transmitted to the display module 11, and the display module 11 may process the provided signals and output image information through a display screen.

The power module 14 may include a power supply module such as a power adapter or a battery device, and a power conversion module which converts a power supplied by the power supply module to generate a power required for an operation of the electronic device 10.

At least one of components of the above-described electronic device 10 may be included in a display device according to embodiments. Additionally, some of individual modules which are functionally included in one module may be included in the display device, and some of other modules may also be provided separately from the display device. For example, the display device may include the display module 11, and the processor 12, the memory 13, and the power module 14 may be provided in a form of another device other than the display device in the electronic device 10.

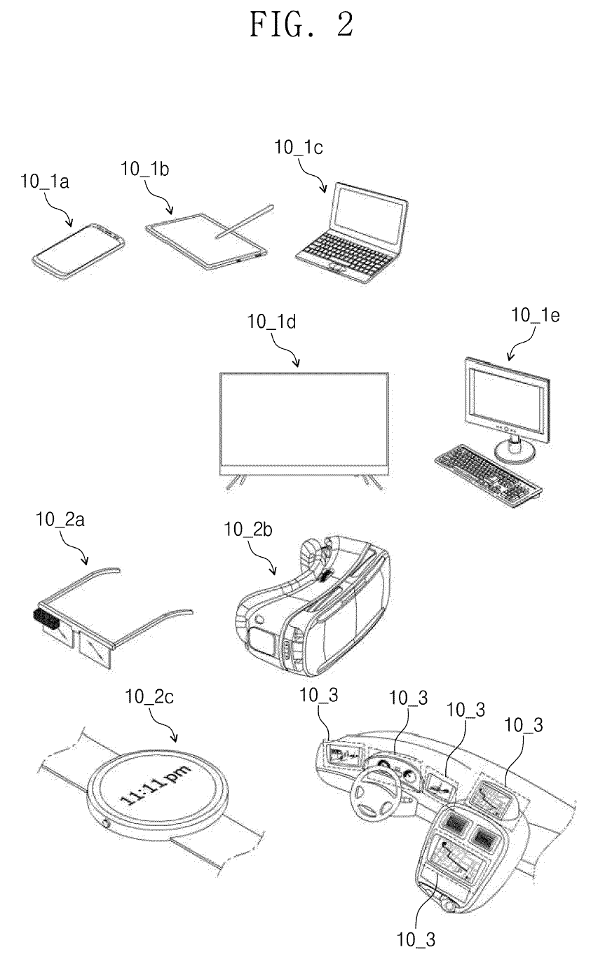

FIG. 2 is a schematic view of electronic devices according to various embodiments.

Referring to FIG. 2, the electronic device to which the display device according to embodiments is applied may include an electronic device for displaying images such as a smart phone 10_1a, a tablet computer 10_1b, a laptop computer 10_1c, a television 10_1d, a desktop monitor 10_1e, and a wearable electronic device including the display module such as a smart glasses 10_2a, a head mounted display 10_2b, a smart watch 10_2c as well as an automobile electronic device 10_3 including the display module such as a center information display (CID) disposed on an instrument panel, a center fascia, or a dashboard of a car, and a room mirror display.

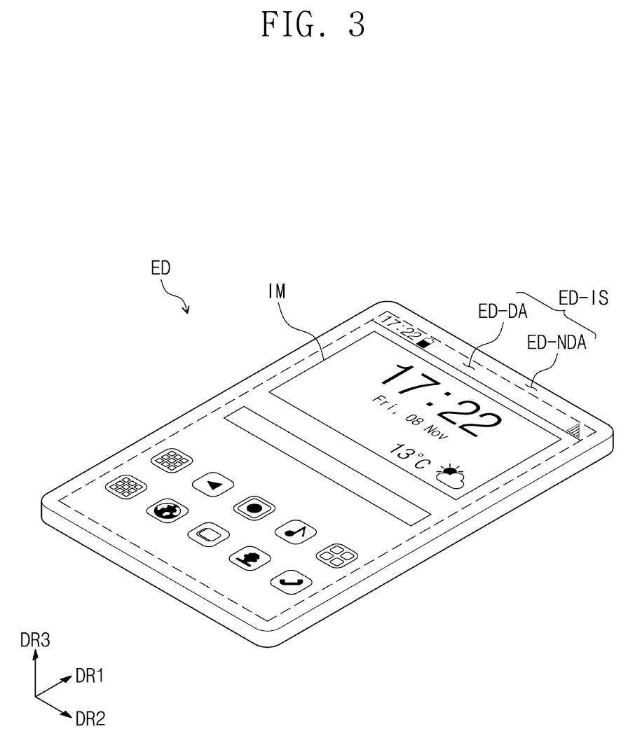

Hereinafter, FIGS. 3 to 6 exemplarily illustrate smart phones as electronic devices according to various embodiments.

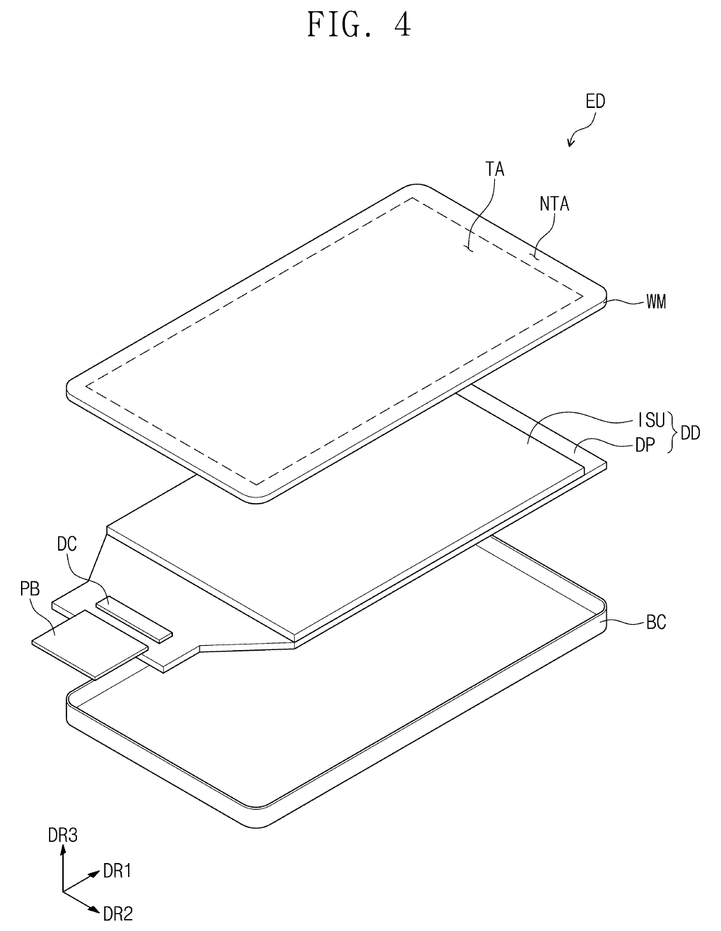

FIG. 3 is a combined perspective view of an electronic device ED according to an embodiment of the inventive concept. FIG. 4 is an exploded perspective view of an electronic device ED according to the embodiment of the inventive concept.

Referring to FIG. 3, the electronic device ED may display an image IM through a display surface ED-IS. Icon images are exemplarily illustrated as the image IM. The display surface ED-IS is parallel to a plane defined by a first direction DR1 and a second direction DR2. A normal direction of the display surface ED-IS, that is, a thickness direction of the electronic device ED is indicated by a third direction DR3. In this specification, the wording “in a plan view,” “when viewed on a plane” or “on a plane” may mean a case when viewed in the third direction DR3. A front surface (or an upper surface) and a rear surface (or a lower surface) of each layer or unit to be described below are defined on the basis of the third direction DR3.

Additionally, the display surface ED-IS includes a display region ED-DA in which the image IM is displayed, and a non-display region ED-NDA adjacent to the display region ED-DA. The non-display region ED-NDA is a region in which an image is not displayed. However, an embodiment of the inventive concept is not limited thereto, and the non-display region ED-NDA may be adjacent to any one side of the display region ED-DA or may be omitted.

Referring to FIG. 4, the electronic device ED may include a window WM, a display device DD, and a housing BC. The housing BC may accommodate the display device DD and be coupled to the window WM. Although not illustrated, the electronic device ED may further include other electronic modules which are accommodated in the housing BC and are electrically connected to a display panel DP. For example, the electronic device ED may further include a main board, a circuit module mounted on the main board, a camera module, a power module, etc.

The window WM may be disposed on an upper part of the display device DD, and transmit, to the outside, an image provided from the display device DD. The window WM includes a transmission region TA and a non-transmission region NTA. The transmission region TA may overlap the display region ED-DA of FIG. 1, and have a shape corresponding to that of the display region ED-DA.

The non-transmission region NTA may overlap the non-display region ED-NDA (see FIG. 3) and have a shape corresponding to that of the non-display region ED-NDA (see FIG. 3). The non-transmission region NTA may be a region having a relatively lower light transmittance than the transmission region TA.

The display device DD may generate an image and detect an external input. The display device DD includes a display panel DP and an input sensor ISU. Although not illustrated, the display device DD may further include an anti-reflection member disposed on the input sensor ISU. The anti-reflection member may include a polarizer and a retarder, or a color filter and a black matrix.

According to an embodiment of the inventive concept, the display panel DP may be a light-emitting display panel, but the type of the display panel DP is not particularly limited. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, a nano LED, etc. Hereinafter, the display panel DP is described as an organic light-emitting display panel.

The input sensor ISU may include any one of a capacitive sensor, an optical sensor, an ultrasonic sensor, or an electromagnetic induction sensor. The input sensor ISU may be formed on the display panel DP through a continuous process, or may be manufactured separately and then attached to an upper side of the display panel DP via an adhesive layer.

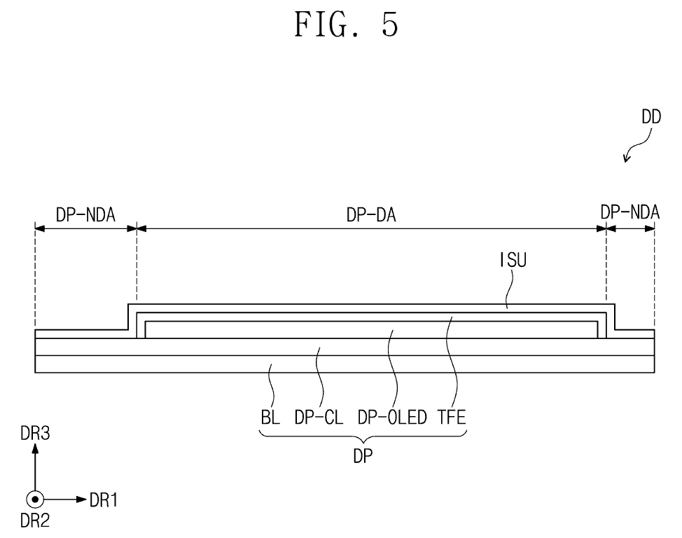

The display device DD according to an embodiment may further include a driver chip package DCP and a circuit board PB. An embodiment of the display panel DP on which the driver chip package DCP is mounted is illustrated, but is not limited thereto. The driver chip package DCP may generate a driving signal required for an operation of the display panel DP in respond to a control signal transmitted from the circuit board PB. The circuit board PB bonded to the display panel DP may be bent and disposed on a rear surface of the display panel DP. The circuit board PB may be disposed on one end of a base layer BL (see FIG. 5) and be electrically connected to a circuit element layer DP-CL (see FIG. 5).

In the display device DD according to an embodiment, a portion of the display panel DP may be bent such that the driver chip package DCP faces downward. Also, a portion of the non-display region ED-NDA (see FIG. 3) of the display panel DP may also be bent. However, a bending portion is not limited thereto, and the circuit board PB may be bent.

As described above, the electronic device ED is illustrated as a smart phone, but in this specification, the electronic device ED may be any device including two or more bonded electronic components. The display panel DP and the driver chip package DCP mounted on the display panel DP respectively correspond to different electronic components, and the electronic device ED may include only these components. Only the display panel DP and the circuit board PB connected to the display panel DP may constitute the electronic device ED, and only a main board and an electronic module mounted on the main board may constitute the electronic device ED. Hereinafter, the description of the electronic device ED according to the inventive concept will be mainly focused on a bonding structure of the display panel DP and the driver chip package DCP mounted on the display panel DP.

FIG. 5 is a cross-sectional view of a display device DD according to embodiment of the inventive concept.

Referring to FIG. 5, the display device DD may include a display panel DP and an input sensor ISU. The display panel DP may include a base layer BL, a circuit element layer DP-CL disposed on the base layer BL, a display element layer DP-OLED, and a thin-film encapsulation layer TFE. The input sensor ISU may be disposed on the thin-film encapsulation layer TFE.

The display panel DP includes a display region DP-DA and a non-display region DP-NDA. The display region DP-DA of the display panel DP corresponds to the display region ED-DA illustrated in FIG. 3 or the transmission region TA illustrated in FIG. 4, and the non-display region DP-NDA corresponds to the non-display region ED-NDA illustrated in FIG. 3 or the non-transmission region NTA illustrated in FIG. 4.

The base layer BL may include the display region DP-DA and the non-display region DP-NDA around the display region DP-DA. The base layer BL may include a synthetic resin film. The base layer BL may have a multi-layered structure. For example, the base layer BL may also have a three-layered structure of a synthetic resin layer, an inorganic layer, and a synthetic resin layer. In particular, the synthetic resin layer may be a polyimide-based resin layer, and materials thereof are not particularly limited. The synthetic resin layer may include at least one of an acryl-based resin, a methacryl-based resin, polyisoprene, a vinyl-based resin, an epoxy-based resin, a urethane-based resin, a cellulose-based resin, a siloxane-based resin, a polyamide-based resin, or a perylene-based resin. Additionally, the base layer BL may include a glass substrate, a metal substrate, or an organic/inorganic composite material substrate, etc.

The circuit element layer DP-CL may include at least one insulating layer and a circuit element. The at least one insulating layer may include at least one inorganic layer and at least one organic layer. The circuit element may include signal lines, a pixel driving circuit, etc. An insulating layer, a semiconductor layer, and a conductive layer are formed through coating process, deposition process, etc. Thereafter, the insulating layer, the semiconductor layer, and the conductive layer may be selectively patterned through a photolithography process. In this process, a semiconductor pattern, a conductive pattern, a signal line, etc., are formed. Patterns disposed at the same layer are formed through the same process. Hereinafter, the wording “patterns are formed through the same process” means that the patterns include the same material and have the same stacked structure.

A display element layer DP-OLED may include an organic light-emitting element. The display element layer DP-OLED may further include an organic layer such as a pixel-defining film.

The thin-film encapsulation layer TFE may be disposed on the circuit element layer DP-CL so as to cover the display element layer DP-OLED. The thin-film encapsulation layer TFE may protect pixels against moisture, oxygen, and external foreign substances. However, an embodiment of the inventive concept is not limited thereto, and the thin-film encapsulation layer TFE may further include an additional insulating layer other than the thin-film encapsulation layer TFE. For example, an optical insulating layer for controlling a refractive index may be further included.

The input sensor ISU may be directly disposed on the display panel DP. In this specification, the wording, "A component being directly disposed on a B component" means that an adhesive layer is not disposed between the A component and the B component. In this embodiment, the input sensor ISU and the display panel DP may be manufactured through a continuous process. However, the idea of the inventive concept is not limited thereto, and the input sensor ISU may be provided as a separate panel and be coupled to the display panel DP via the adhesive layer. According to an embodiment, the input sensor ISU may also be omitted.

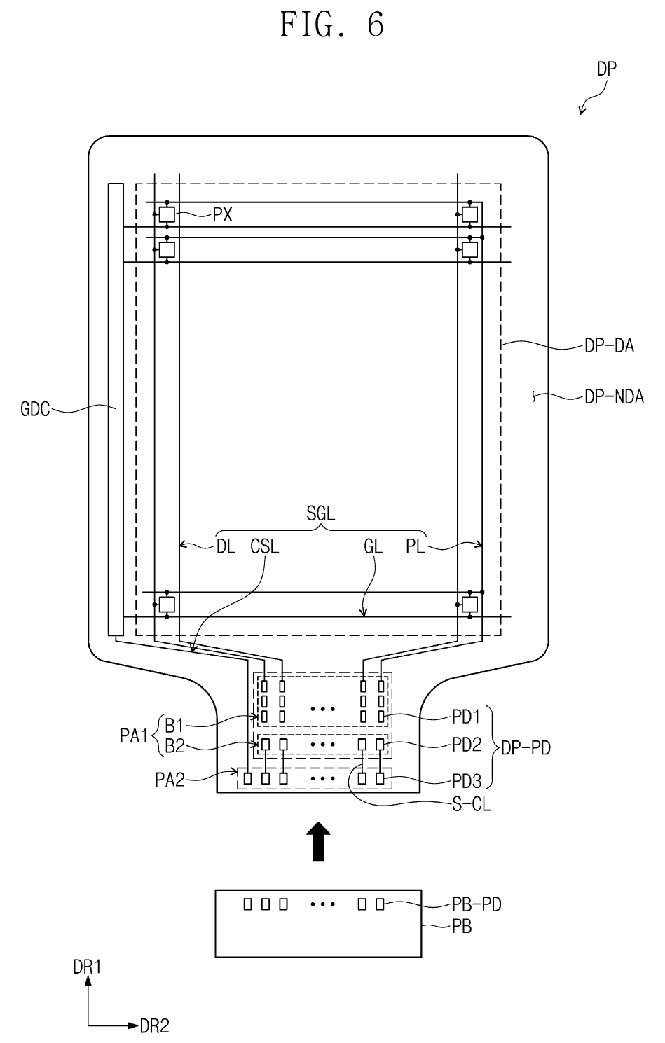

FIG. 6 is a plan view of a display panel DP according to an embodiment of the inventive concept.

Referring to FIG. 6, the display panel DP may include a plurality of pixels PX, a gate driving circuit GDC, a plurality of signal lines SGL, and a plurality of signal pads DP-PD.

The pixels PX are disposed in the display region DP-DA. The pixels PX each include a light-emitting element and a pixel driving circuit connected to the light-emitting element. The gate driving circuit GDC and the signal lines SGL may be included in the circuit element layer DP-CL illustrated in FIG. 5.

The gate driving circuit GDC sequentially outputs gate signals to a plurality of gate lines GL. A transistor of the gate driving circuit GDC may be formed through the same process as that for a transistor of the pixel PX, for example, a low temperature polycrystalline silicon (LTPS) process or a low temperature polycrystalline oxide (LTPO) process. The display panel DP may also further include another driving circuit which provides a light-emitting control signal to the pixels PX.

The signal lines SGL may include gate lines GL, data lines DL, a power line PL, and a control signal line CSL. The gate lines GL are respectively connected to corresponding pixels PX among the pixels PX, and the data lines DL are respectively connected to corresponding pixels PX among the pixels PX. The power line PL is connected to the pixels PX. The control signal line CSL may be connected to the gate driving circuit GDC to provide control signals to the gate driving circuit GDC.

The signal lines SGL may be disposed in the display region DP-DA and the non-display region DP-NDA. The signal lines SGL may each include a pad part and a line part. The line part may be disposed in the display region DP-DA and the non-display region DP-NDA. The pad part is connected to a terminal of the line part. The pad part may be disposed in a pad region to be described later.

The plurality of signal pads DP-PD may include first signal pads PD1 which is an output pad, second signal pads PD2 which is an input pad, and third signal pads PD3. A region in which the first signal pads PD1 and the second signal pads PD2 are disposed may be defined as a first pad region PA1 and a region in which the third signal pads PD3 are disposed may be defined as a second pad region PA2.

The first pad region PA1 is a region to which the driver chip package DCP (see FIG. 4) is bonded, and the second pad region PA2 is a region to which the circuit board PB is bonded. The first pad region PA1 may include a first region B1 in which the first signal pads PD1 are disposed, and a second region B2 in which the second signal pads PD2 are disposed. The first pad region PA1 and the second pad region PA2 may be disposed in the non-display region DP-NDA. The first pad region PA1 and the second pad region PA2 may be spaced apart from each other in the first direction DR1. The first pad region PA1 may be further adjacent to the display region DP-DA than the second pad region PA2, and the second pad region PA2 may be spaced apart from the display region DP-DA with the first pad region PA1 between the second pad region PA2 and the display region DP-DA.

At least some of the first signal pads PD1 may be respectively connected to the corresponding data lines DL. The second signal pads PD2 may be connected to the third signal pads PD3 via connection signal lines S-CL. It is exemplarily illustrated that three pad rows are disposed in the first region B1, but an embodiment of the inventive concept is not limited thereto. Fewer pad rows may be disposed, as well as more pad rows may be disposed in the first region B1.

The circuit board PB may include a plurality of circuit pads PB-PD. The circuit pads PB-PD may be arranged in the second direction DR2. The circuit pads PB-PD of the circuit board PB may be bonded to the third signal pads PD3 of the second pad region PA2 via an anisotropic conductive adhesive layer, a solder bump, or the like.

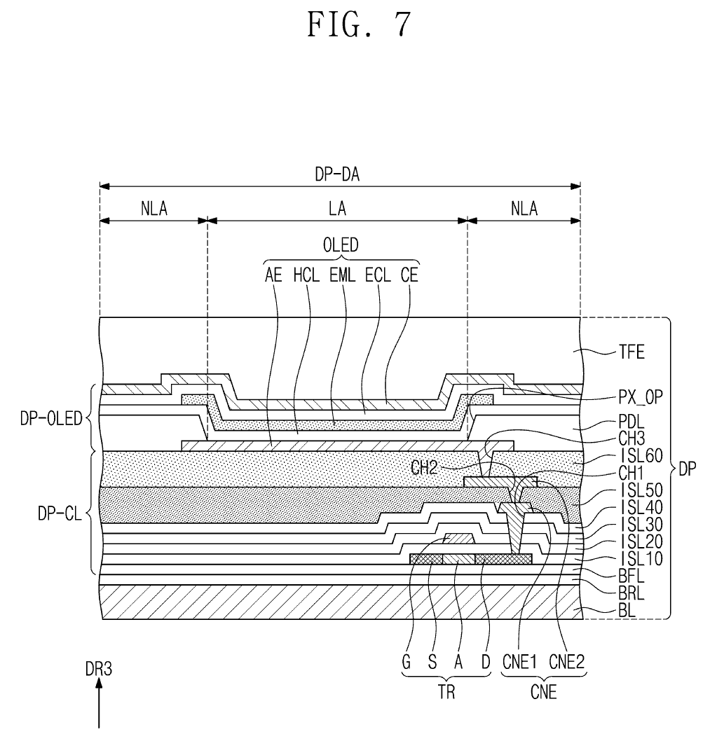

FIG. 7 is a cross-sectional view of a display panel DP according to an embodiment of the inventive concept.

Referring to FIG. 7, the display panel DP may include a base layer BL, a circuit element layer DP-CL disposed on the base layer BL, a display element layer DP-OLED, and a thin-film encapsulation layer TFE.

A plurality of insulating layers are disposed on an upper surface of the base layer BL. The plurality of insulating layers may include a barrier layer BRL and a buffer layer BFL. The plurality of insulating layers may further include a first insulating layer ISL10 to a sixth insulating layer ISL60. The barrier layer BRL prevents foreign substances from being introduced from the outside. The barrier layer BRL may include a silicon oxide layer and/or a silicon nitride layer. The silicon oxide layer and the silicon nitride layer may each be provided in plurality, and the silicon oxide layers and the silicon nitride layers may be alternately stacked.

The buffer layer BFL improves a bonding force between the base layer BL and a semiconductor pattern and/or a conductive pattern. The buffer layer BFL may include a silicon oxide layer and/or a silicon nitride layer. The silicon oxide layer and the silicon nitride layer may be alternately stacked.

The semiconductor pattern may be disposed on the buffer layer BFL. The semiconductor pattern may include an amorphous or crystalline silicon semiconductor, or a metal oxide semiconductor. The semiconductor pattern may be doped with an N-type dopant or a P-type dopant. The semiconductor pattern may include a highly-doped region and a lightly-doped region. The highly-doped region may have conductivity higher than that of the lightly-doped region, and substantially serve as a source electrode and a drain electrode of a transistor TR. The lightly-doped region may substantially correspond to an active (or a channel) of the transistor TR.

A source S, an active A, and a drain D of the transistor TR may be formed from the semiconductor pattern. The first insulating layer ISL10 may be disposed on the semiconductor pattern. A gate G of the transistor TR may be disposed on the first insulating layer ISL10. The second insulating layer ISL20 may be disposed on the gate G. The third insulating layer ISL30 may be disposed on the second insulating layer ISL20. The fourth insulating layer ISL40 may be disposed on the third insulating layer ISL30.

A connection electrode CNE may include a first connection electrode CNE1 and a second connection electrode CNE2 for connecting the transistor TR and a light-emitting element OLED. The first connection electrode CNE1 may be disposed on the fourth insulating layer ISL40 and be connected to the drain D via a first contact hole CH1 defined in the first to fourth insulating layers ISL10 to ISL40.

The fifth insulating layer ISL50 may be disposed on the fourth insulating layer ISL40. The second connection electrode CNE2 may be disposed on the fifth insulating layer ISL50. The second connection electrode CNE2 may be connected to the first connection electrode CNE1 via a second contact hole CH2 defined in the fifth insulating layer ISL50. The second connection electrode CNE2 may be the data line DL of FIG. 4.

The sixth insulating layer ISL60 may be disposed on the second connection electrode CNE2. The layers ranging from the buffer layer BFL to the sixth insulating layer ISL60 may be defined as the circuit element layer DP-CL. The first insulating layer ISL10 to the sixth insulating layer ISL60 may each be an inorganic layer or an organic layer.

A first electrode AE may be disposed on the sixth insulating layer ISL60. The first electrode AE may be connected to the second connection electrode CNE2 via a third contact hole CH3 defined in the sixth insulating layer ISL60. The first electrode AE may be connected to the transistor TR via the first and second connection electrodes CNE1 and CNE2. A pixel-defining film PDL, in which an opening PX_OP for exposing a predetermined portion of the first electrode AE is defined, may be disposed on the first electrode AE and the sixth insulating layer ISL60.

A hole control layer HCL may be disposed on the first electrode AE and the pixel-defining film PDL. The hole control layer HCL may include a hole transport layer and a hole injection layer.

A light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate light having one color of red, green, or blue.

An electron control layer ECL may be disposed on the light-emitting layer EML and the hole control layer HCL. The electron control layer ECL may include an electron transport layer and an electron injection layer. The hole control layer HCL and the electron control layer ECL may be disposed in a light-emitting region LA and a non-light-emitting region NLA in common.

A second electrode CE may be disposed on the electron control layer ECL. The second electrode CE may be disposed in the pixels PX (see FIG. 6) in common. The layer, on which the light-emitting element OLED is disposed, may be defined as the display element layer DP-OLED.

The thin-film encapsulation layer TFE may be disposed on the second electrode CE to cover the pixels PX (see FIG. 6). Although not illustrated, the thin-film encapsulation layer TFE may be formed of a plurality of layers. Some of the plurality of layers may include an inorganic insulating layer and protect the pixels PX (see FIG. 4) against moisture or oxygen. The others of the plurality of layers may include an organic insulating layer and protect the pixels PX (see FIG. 4) against foreign substances such as dust particles.

A first voltage may be applied to the first electrode AE via the transistor TR and a second voltage having a level lower than that of the first voltage may be applied to the second electrode CE. Holes and electrons injected into the light-emitting layer EML are combined to form excitons and the excitons transition to a ground state, so that the light-emitting element OLED may emit light.

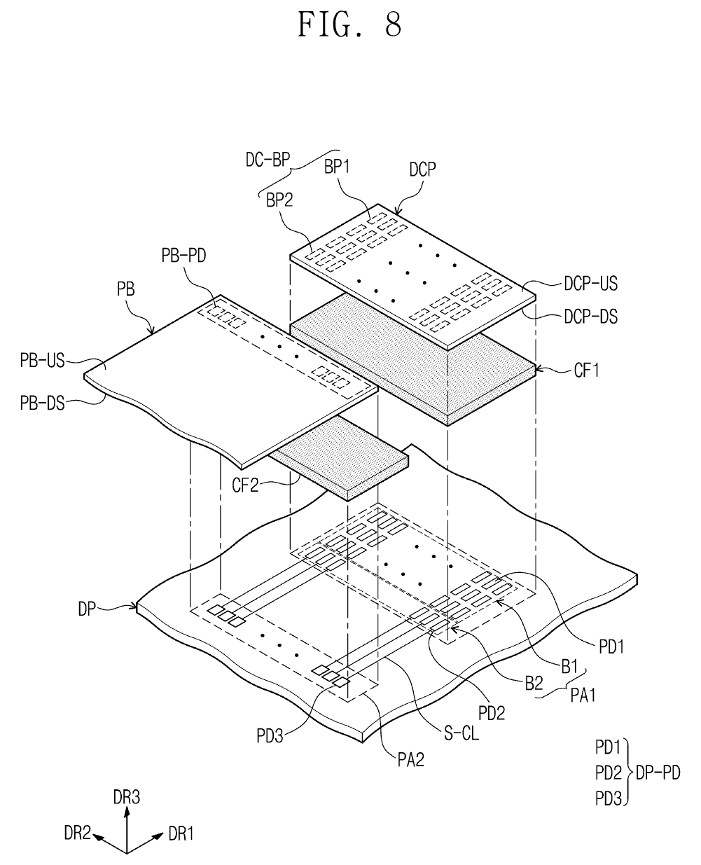

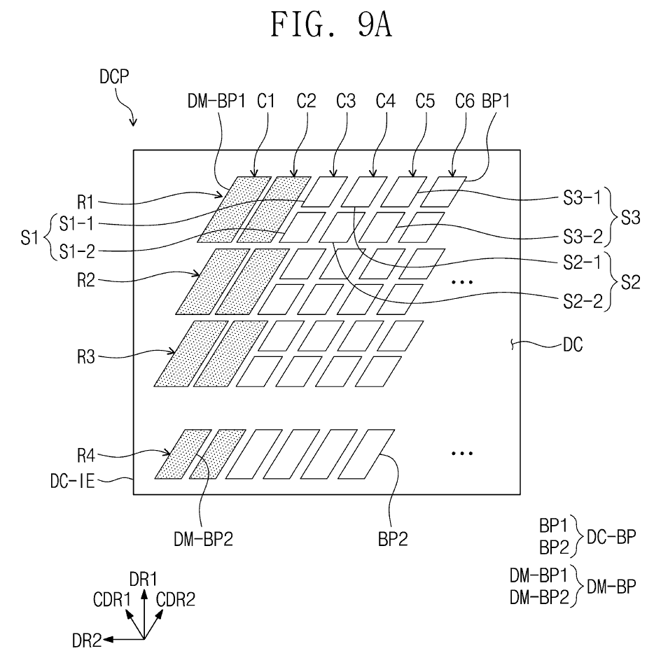

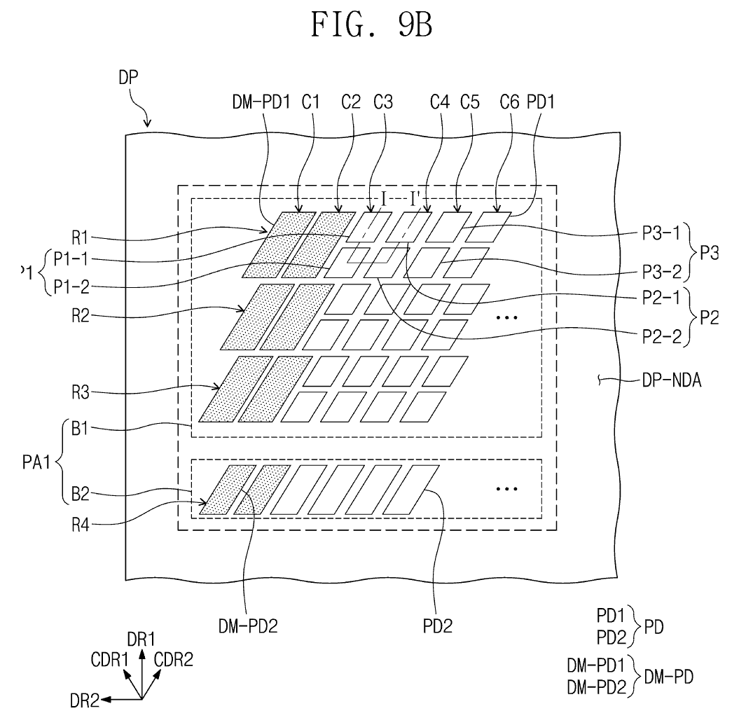

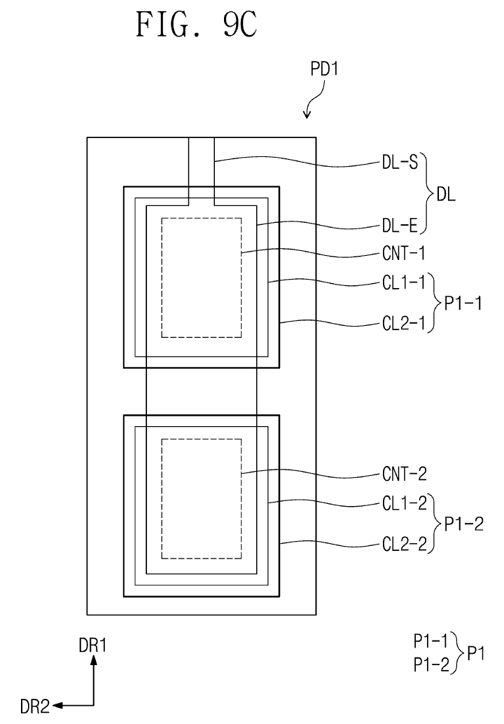

FIG. 8 is an exploded perspective view of a bonding region according to an embodiment of the inventive concept. FIG. 9A is a plan view illustrating an arrangement of chip bumps DC-BP on a driver chip DC according to an embodiment of the inventive concept. FIG. 9B is a plan view of a first pad region PA1 of a display panel DP according to an embodiment of the inventive concept. FIG. 9C is an enlarged plan view of the first signal pad PD1 according to an embodiment of the inventive concept.

For example, FIG. 8 illustrates that a driver chip package DCP and a circuit board PB are exploded from a display panel DP. For convenience of description, FIG. 8 illustrates a planar shape of a chip bump DC-BP as a dotted line on an upper surface DCP-US of the driver chip package DCP, but output bumps BP1 and input bumps BP2 each have a shape of protruding from a lower surface DCP-DS of the driver chip package DCP and being exposed to the outside.

According to an embodiment of the inventive concept, the driver chip package DCP may be bonded to a first pad region PA1 via a first conductive adhesive layer CF1, and the circuit board PB may be bonded to a second pad region PA2 via a second conductive adhesive layer CF2. The driver chip package DCP includes output bumps BP1 electrically connected to the respective first signal pads PD1 and input bumps BP2 electrically connected to the respective second signal pads PD2.

The driver chip package DCP receives first signals from the outside via the second signal pads PD2 and the input bumps BP2. The driver chip package DCP provides second signals generated according to the first signals to the first signal pads PD1 via the output bumps BP1. For example, the driver chip package DCP may include a data driving circuit. The first signal may be an image signal which is a digital signal applied from the outside, and the second signal may be a data signal which is an analog signal. The driver chip package DCP may generate an analog voltage corresponding to a grayscale value of the image signal and provide the data signal, which is the second signal, to the pixels PX via the data line DL illustrated in FIG. 6.

The circuit board PB may include an upper surface PB-US and a lower surface PB-DS, and the lower surface PB-DS of the circuit board PB may be a surface facing the third signal pads PD3. The circuit board PB may include a plurality of circuit pads PB-PD electrically connected to the third signal pads PD3. The circuit pads PB-PD may be disposed on the lower surface PB-DS of the circuit board PB and be arranged in the second direction DR2. The circuit board PB may provide a video signal, a driving voltage, and other control signals to the driver chip package DCP. FIG. 8 illustrates that the circuit board PB includes the circuit pads PB-PD. However, an embodiment of the inventive concept is not limited thereto, and the circuit board PB may also be electrically connected to the third signal pads PD3 via the circuit bump.

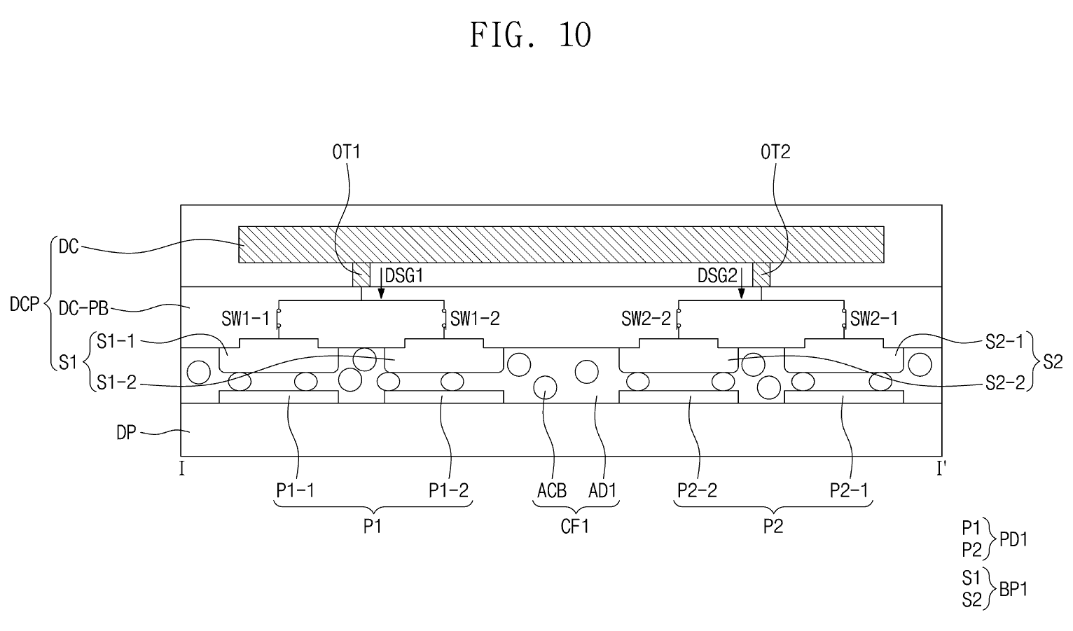

In this embodiment, the driver chip package DCP may include a driver chip DC and a package substrate DC-PB (see FIG. 10) to be described later. Referring to FIG. 9A, an edge DC-IE of the driver chip DC may be defined to have a quadrangular shape on a plane defined by the first direction DR1 and the second direction DR2. However, a planar shape of the driver chip DC is not particularly limited.

Chip bumps DC-BP and dummy bumps DM-BP may be arranged on the driver chip DC. The bumps on the driver chip DC of FIG. 9A may be spaced apart from each other in a matrix form. For example, the bumps of the driver chip DC may define a plurality of columns C1, C2, C3, C4, C5, and C6 extending in the first direction DR1, and a plurality of rows R1, R2, R3, and R4 extending in the second direction DR2. In this specification, the first direction DR1 may be referred to as a column direction, and the second direction DR2 may also be referred to as a row direction. A first oblique direction CDR1 may mean a direction crossing with respect to the first direction DR1 and the second direction DR2, and a second oblique direction CDR2 may mean a direction symmetrical to the first oblique direction CDR1 with respect to the first direction DR1.

FIG. 9A is an enlarged plan view of a portion of the driver chip DC. The chip bumps DC-BP and the dummy bumps DM-BP may extend in the second oblique direction CDR2. The chip bumps DC-BP and the dummy bumps DM-BP may extend in the first oblique direction CDR1 in another portion of the driver chip DC, and may also extend in the first direction DR1 at the center portion of the driver chip DC.

In an embodiment, the first to third rows R1, R2, and R3 may be output rows, and the fourth row R4 may be an input row. The distances between the output rows in the first direction DR1 may be smaller than the distances between the output rows and the input rows in the first direction DR1. The chip bumps DC-BP arranged in the first to third rows R1, R2, and R3 may be the output bumps BP1, and the dummy bumps DM-BP arranged in the first to third rows R1, R2, and R3 may be output dummy bumps DM-BP1. The chip bumps DC-BP arranged in the fourth row R4 may be the input bumps BP2, and the dummy bumps DM-BP arranged in the fourth row R4 may be input dummy bumps DM-BP2.

According to an embodiment of the inventive concept, the output bumps BP1 may each include bumps which are divided and spaced apart from each other along the first direction DR1. For example, a first output bump S1, of the output bumps BP1, which is disposed in the third column C3 of the first row R1 may include a first bump S1-1 and a second bump S1-2 which is spaced apart from the first bump S1-1 along the first direction DR1. The first bump S1-1 and the second bump S1-2 may output the same data signal.

The first bump S1-1 of the first output bump S1 may be electrically connected to a first pad P1-1 of a first output pad P1 (see FIG. 9B) to be described later, and the second bump S1-2 of the first output bump S1 may be electrically connected to a second pad P1-2 of the first output pad P1 (see FIG. 9B) to be described later.

On the contrary, the input bumps BP2 disposed in the fourth row R4 may not be divided along the first direction DR1. However, an embodiment of the inventive concept is not limited thereto, and similar to the output bumps BP1, some of the input bumps BP2 may also include bumps which are divided and are spaced apart from each other in the first direction DR1.

In an embodiment, the plurality of output bumps BP1 may include the first output bump S1, a second output bump S2, and a third output bump S3 which are disposed in the first row R1 and spaced apart from each other along the second direction DR2. As described above, the first output bump S1, the second output bump S2, and the third output bump S3 may respectively include first bumps S1-1, S2-1, and S3-1, and second bumps S1-2, S2-2, and S3-2 spaced apart from each other along the first direction DR1. The first output bump S1, the second output bump S2 and the third output bump S3 may respectively output different data signals.

According to an embodiment of the inventive concept, the dummy bumps DM-BP may be disposed between the outermost chip bump of the chip bumps DC-BP and the edge DC-IE of the driver chip DC. For example, the dummy bumps DM-BP may each be arranged in the first column C1 and the second column C2, but the number of columns is not limited. The dummy bumps DM-BP may be disposed at the outermost side of each of the first to fourth rows R1, R2, R3, and R4 to fill a space between the chip bumps DC-BP and the edge DC-IE of the driver chip DC. Additionally, the dummy bumps DM-BP correspond to dummy pads DM-PD of FIG. 9B to be described later, and may indicate electrically isolated floating bumps.

The dummy bumps DM-BP may not be divided along the first direction DR1. The dummy bumps DM-BP are not electrically connected to the pads outputting a signal but are electrically connected to the dummy pads DM-PD , and thus are not required to be spaced apart from each other. The dummy bumps DM-BP may also extend in the second oblique direction CDR2 and have an integral shape, and shapes of the dummy bumps DM-BP are not limited thereto. The dummy bumps DM-BP may be in contact with the dummy pads DM-PD of FIG. 9B to be described later and evenly distribute pressures occurring during a bonding process.

FIG. 9B is an enlarged plan view of a portion of the first pad region PA1 and the second pad region PA2 illustrated in FIG. 8, and signal pads PD and the dummy pads DM-PD may extend along the second oblique direction CDR2. The signal pads PD and the dummy pads DM-PD may extend in the first oblique direction CDR1 in another portion of the first pad region PA1, and may also extend in the first direction DR1 at the center portion of the first pad region PA1. The second pad region PA2 illustrated in FIG. 8 may also be arranged in a form similar to that of the first pad region PA1 of FIG. 9B.

The bumps of the driver chip DC described with reference to FIG. 9A may be bonded to the first pad region PA1. In the first pad region PA1, first signal pads PD1 corresponding to the output bumps BP1 and output dummy pads DM-PD1 corresponding to the output dummy bumps DM-BP1 may be disposed in a first region B1, and second signal pads PD2 corresponding to the input bumps BP2 and input dummy pads DM-PD2 corresponding to the input dummy bumps DM-BP2 may be disposed in a second region B2.

In an embodiment, the signal pads PD arranged in the first to third rows R1, R2, and R3 may be referred to as the output pads PD1, and the dummy pads DM-PD arranged in the first to third rows R1, R2, and R3 may be referred to as the output dummy pads DM-PD1. The signal pads PD arranged in the fourth row R4 may be referred to as input pads PD2, and the dummy pads DM-PD arranged in the fourth row R4 may be referred to as input dummy pads DM-PD2.

According to an embodiment of the inventive concept, the output pads PD1 may each include pads which are divided and are spaced apart from each other along the first direction DR1. For example, a first output pad P1, of the output pads PD1, which is disposed in the third column C3 of the first row R1 may include a first pad P1-1 and a second pad P1-2 which is spaced apart from the first pad P1-1 along the first direction DR1. The first pad P1-1 and the second pad P1-2 may receive the same data signal output from the first output bump S1 (see FIG. 9A). That is, the first pad P1-1 and the second pad P1-2 may transmit the received data signal to the data line DL (see FIG. 6) corresponding to the first output pad P1.

The input pads PD2 disposed in the fourth row R4 may not be divided along the first direction DR1. However, an embodiment of the inventive concept is not limited thereto, and similar to the output pads PD1, some of the input pads PD2 may also include pads which are divided and are spaced apart from each other along the first direction DR1.

In an embodiment, a plurality of output pads PD1 may include the first output pad P1, a second output pad P2, and a third output pad P3 disposed in the first row R1 and spaced apart from each other along the second direction DR2. As described above, the first output pad P1, the second output pad P2, and the third output pad P3 may respectively include first pads P1-1, P2-1, and P3-1, and second pads P1-2, P2-2, and P3-2 spaced apart from each other along the first direction DR1. The first output pad P1, the second output pad P2 and the third output pad P3 may respectively receive different data signals which are output from the first output bump S1, the second output bump S2 and the third output bump S3 illustrated in FIG. 9A.

According to an embodiment of the inventive concept, the dummy pads DM-PD corresponding to the dummy bumps DM-BP (see FIG. 9A) are disposed. The dummy pads DM-PD may be spaced apart from the signal pads PD in the second direction DR2. The dummy pads DM-PD may be electrically isolated conductive patterns, that is, floating patterns. The dummy pads DM-PD and the signal pads PD may be formed through the same process and include the same material.

The dummy pads DM-PD may not be divided along the first direction DR1. Since signals from the dummy bumps DM-BP are not transmitted to the dummy pads DM-PD, the dummy pads DM-PD are not required to include pads having a divided form. The dummy pads DM-PD may extend in the second oblique direction CDR2 and have an integral shape so as to be in contact with the dummy bumps DM-BP, and shapes of dummy pads DM-PD are not limited.

FIG. 9C is an enlarged plan view of the first signal pad PD1 according to an embodiment of the inventive concept. The first output pad P1 is exemplarily illustrated as the first signal pad PD1, but is not limited thereto. The first output pad P1 may include a first pad P1-1 and a second pad P1-2 spaced apart from the first pad P1-1 in the first direction DR1. The first pad P1-1 and the second pad P1-2 may respectively include first conductive patterns CL1-1 and CL1-2, and second conductive patterns CL2-1 and CL2-2 disposed on the first conductive patterns CL1-1 and CL1-2.

FIG. 9C exemplarily illustrates, as a signal line, a data line DL including a terminal part DL-E and a line part DL-S which have different widths, but an embodiment of the inventive concept is not limited thereto. In this specification, a width may mean a length or a lateral dimension of the terminal part DL-E or the line part DL-S in the second direction DR2. However, the data line DL which includes the terminal part DL-E and the line part DL-S may have a uniform width.

On a plane, the terminal part DL-E may have a shape extending in the first direction DR1, and the length in the first direction DR1 may be greater than the length in the second direction DR2.

On a plane, contact holes CNT-1 and CNT-2 may overlap the terminal part DL-E, and the first conductive patterns CL1-1 and CL1-2 may be electrically connected to the terminal part DL-E of the data line DL via the contact holes CNT-1 and CNT-2. The contact holes CNT-1 and CNT-2 may be spaced apart from each other along the first direction DR1.

Referring to FIGS. 7 and 9C together, the terminal part DL-E may be disposed on the first insulating layer ISL10. That is, the terminal part DL-E and the gate G may be disposed at the same layer. The terminal part DL-E and the gate G may be formed through the same process and may include the same material.

The first conductive patterns CL1-1 and CL1-2 may be disposed on the fourth insulating layer ISL40 illustrated in FIG. 7. The first conductive patterns CL1-1 and CL1-2, and the first connection electrode CNE1 which is disposed on the fourth insulating layer ISL40 may be disposed at the same layer. The first conductive patterns CL1-1 and CL1-2, and first connection electrode CNE1 may be formed through the same process and include the same material. The first conductive patterns CL1-1 and CL1-2 may be electrically connected to the terminal part DL-E of the data line DL via the contact holes CNT-1 and CNT-2 which pass through the second insulating layer ISL20 to the fourth insulating layer ISL40.

The second conductive patterns CL2-1 and CL2-2 may be disposed on the first conductive patterns CL1-1 and CL1-2. The second conductive patterns CL2-1 and CL2-2, and the second connection electrode CNE2 which is disposed on the fifth insulating layer ISL50 illustrated in FIG. 7 may be disposed at the same layer. The second conductive patterns CL2-1 and CL2-2, and the second connection electrode CNE2 may be formed through the same process and include the same material. The second conductive patterns CL2-1 and CL2-2 may be in direct contact with upper surfaces of the first conductive patterns CL1-1 and CL1-2 to be electrically connected thereto.

On a plane, the first conductive pattern CL1-1 of the first pad P1-1 may be spaced apart from the first conductive pattern CL1-2 of the second pad P1-2 in the first direction DR1. Even though the first conductive pattern CL1-1 of the first pad P1-1 is electrically isolated from the data line DL, the first conductive pattern CL1-2 of the second pad P1-2 may be electrically connected to the data line DL. Similarly, in the first direction DR1, the second conductive pattern CL2-1 of the first pad P1-1 may be spaced apart from the second conductive pattern CL2-2 of the second pad P1-2, and thus even though the second conductive pattern CL2-1 of the first pad P1-1 is electrically isolated from the data line DL, the second conductive pattern CL2-2 of the second pad P1-2 may be electrically connected to the data line DL.

FIG. 10 is a schematic cross-sectional view of a bonding region according to an embodiment of the inventive concept.

FIG. 10 schematically illustrates a cross section of a bonding region taken along line I-I' illustrated in FIG. 9B. A driver chip package DCP may be bonded to a display panel DP via a first conductive adhesive layer CF1. The chip bump DC-BP (see FIG. 9A) may be in contact with a first conductive adhesive layer CF1 and be bonded to the first and second signal pads PD1 and PD2 (see FIG. 9B) of the display panel DP.

In an embodiment, the first conductive adhesive layer CF1 may include an adhesive layer AD1 and a plurality of conductive balls ACB disposed in the adhesive layer AD1. The conductive balls ACB may be arranged in the adhesive layer AD1, and the adhesive layer AD1 may include a binder and surround the conductive balls ACB.

As illustrated in FIG. 10, the conductive balls ACB may be disposed between a first output pad P1 and a first output bump S1 to electrically connect the first output pad P1 and the first output bump S1. Some of the conductive balls ACB disposed between the first output pad P1 and the first output bump S1 may have a deformed shape compared to the conductive balls ACB which do not overlap the first output pad P1 and the first output bump S1 since the adhesive layer AD1 is cured when subjected to a pressure.

The driver chip package DCP may include a driver chip DC, output bumps BP1, and a package substrate DC-PB. The driver chip DC may include a first output terminal OT1 and a second output terminal OT2. The first output terminal OT1 may output a first data signal DSG1 to the first output bump S1, and the second output terminal OT2 may output a second data signal DSG2 to the second output bump S2. The first data signal DSG1 and the second data signal DSG2 may be analog signals obtained by the driver chip DC converting a digital signal applied from the outside.

According to an embodiment of the inventive concept, the first output terminal OT1 may provide the same first data signal DSG1 to each of the first bump S1-1 of the first output bump S1 and the second bump S1-2 of the first output bump S1 which are electrically separated from each other. The first data signal DSG1 may be controlled via switching elements SW1-1 and SW1-2 which are connected in parallel between the driver chip DC and the first output bump S1 within the package substrate DC-PB. The first switching element SW1-1 may control the first data signal DSG1 to the first bump S1-1 of the first output bump S1, and the second switching element SW1-2 may control the first data signal DSG1 to the second bump S1-2 of the first output bump S1. Accordingly, the first bump S1-1 and the second bump S1-2 of the first output bump S1 may be individually driven. However, the first bump S1-1 and the second bump S1-2 of the first output bump S1 may be directly connected to the driver chip via conductive signal lines, respectively.

Referring to FIGS. 9B and 10 together, the first output pad P1 and the second output pad P2 may be disposed in the same first row R1. The first output pad P1 may receive the first data signal DSG1, and the second output pad P2 may receive the second data signal DSG2.

In an embodiment, the first pad P1-1 and the second pad P1-2 of the first output pad P1 may receive the first data signal DSG1, and the first pad P2-1 and the second pad P2-2 of the second output pad P2 may receive the second data signal DSG2. As described above, the first bump S1-1 and the second bump S1-2 of the first output bump S1 may receive the first data signal DSG1 via different path, and thus the first pad P1-1 and the second pad P1-2 of the first output pad P1 may also receive the first data signal DSG1 via different path.

FIG. 10 illustrates that since both the switch elements of the first bump S1-1 and the second bump S1-2 of the first output bump S1 are activated, both the first pad P1-1 and the second pad P1-2 of the first output pad P1 may receive the first data signal DSG1 at the same time. For example, the description is focused on the first output bump S1 and the first output pad P1, but may also be applied to the second output bump S2 and the second output pad P2.

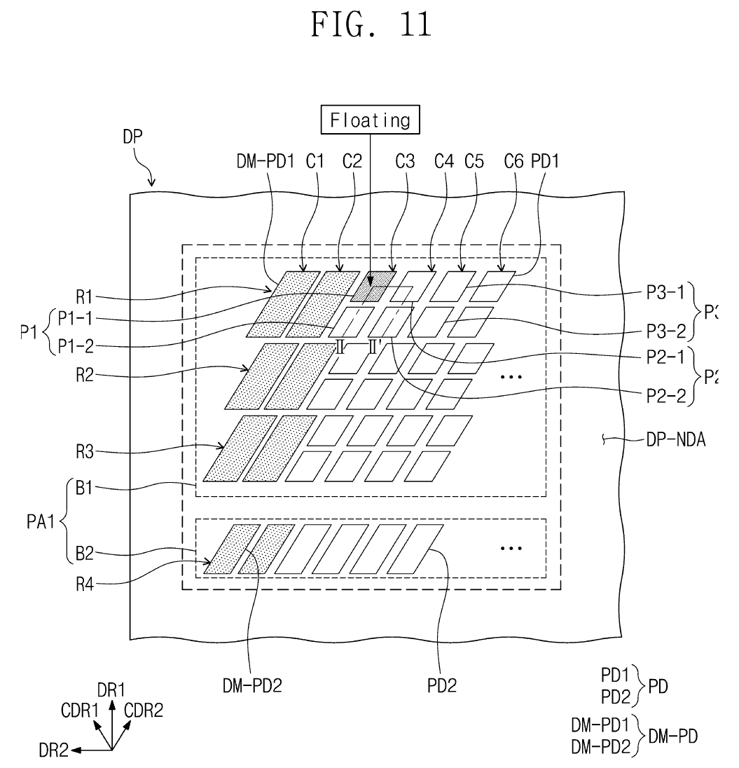

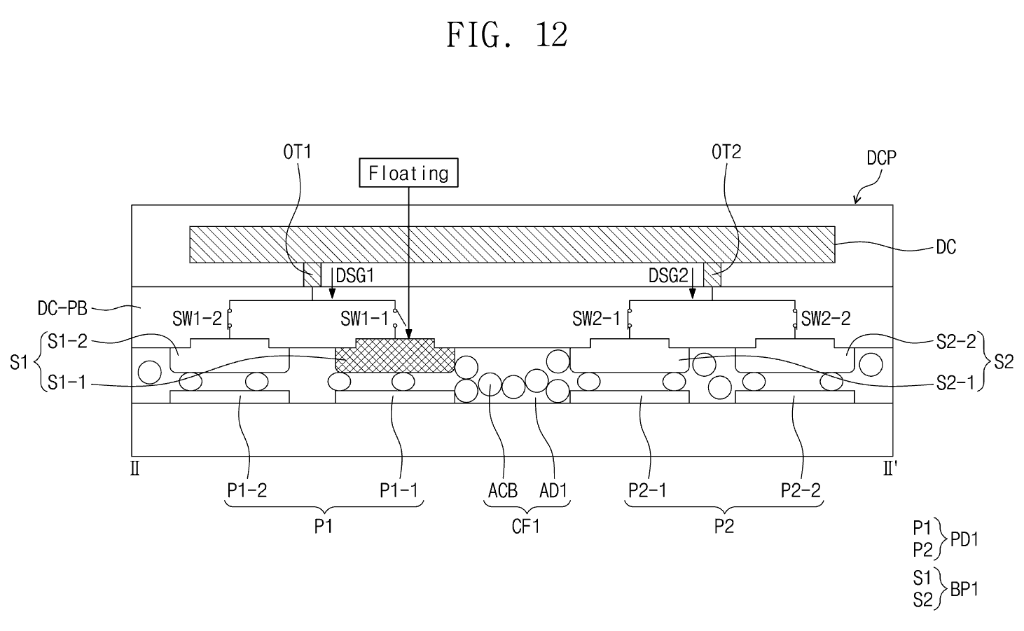

FIG. 11 is a plan view illustrating a state in which one part of pads in a first pad region PA1 according to an embodiment of the inventive concept is shorted, for example, the data signal from the driver chip package DCP is not supplied to the output pad due to open-circuit between the driver chip package DCP and the output pad, and FIG. 12 is a cross-sectional schematic view of the bonding region illustrating a state in which one part of pads according to an embodiment of the inventive concept is shorted.

FIG. 11 illustrates the same pad region as that of FIG. 9B, except that a first pad P1-1 of the first output pad P1 disposed in the third column C3 of the first row R1 is shorted. FIG. 12 schematically illustrates a cross section of a bonding region taken along line II-II' illustrated in FIG. 11. FIG. 12 illustrates that a first pad P1-1 of a first output pad P1 is shorted as the first switching element SW1-1 of FIG. 10 is turned off. Hereinafter, detailed descriptions of the same components as those described with reference to FIGS. 9B and 10 will be omitted.

As illustrated in FIG. 11, the first pad P1-1 of the first output pad P1 may be shorted due to a short occurring between the first pad P1-1 and a first pad P2-1 of an adjacent second output pad P2 or the first pad P1-1 and a second pad P1-2 of the first output pad P1.

Referring to FIG. 12, some of a plurality of conductive balls ACB may be connected between a first bump S1-1 of a first output bump S1 and a first pad P2-1 of a second output pad P2. That is, due to the aggregation of the conductive balls ACB between the first bump S1-1 of a first output bump S1 and a first pad P2-1 of a second output pad P2, a short circuit may occur between the first bump S1-1 of the first output bump S1 and the first pad P2-1 of the second output pad P2. Accordingly, a short may also occur between the first pad P1-1 of the first output pad P1 and the first pad P2-1 of the adjacent second output pad P2.

Even when a short occurs between the first bump S1-1 of the first output bump S1 and the first bump S2-1 of the adjacent second output bump S2, the first bump S1-1 of the first output bump S1 may not output a first data signal DSG1, and the first bump S2-1 of the second output bump S2 may output a second data signal DSG2. Similarly, the first pad P1-1 of the first output pad P1 may not receive the first data signal DSG1, and the first pad P2-1 of the second output pad P2 may receive the second data signal DSG2.

Generally, since some of the plurality of conductive balls ACB electrically connect the adjacent bumps or pads, the data signal DL (see FIG. 6) required for being transmitted from the pad around which a short occurs may not be transmitted to the display panel DP. Referring to FIG. 6 together, when a defect occurs in the data line DL which is disposed on the display panel DP and extends in the first direction DR1, a dark spot may occur along the first direction DR1. That is, since a data signal is not transmitted to the data line DL extending in the first direction DR1, which is a vertical direction, a dark spot, which is a vertical line defect, may occur.

According to the inventive concept, even though a first switching element SW1-1 to which the first data signal DSG1 is transmitted is turned off, a second switching element SW1-2 connected in parallel may remain connected. The first data signal DSG1 may be transmitted to the second pad P1-2 of the first output pad P1 via the second bump S1-2 of the first output bump S1, and thus the occurrence of a vertical line defect and a dark spot may be reduced.

FIG. 12 is a cross-section illustrating the bonding region in which a short occurs between the first bump S1-1 of the first output bump S1 and the first pad P2-1 of the second output pad P2, but an embodiment of the inventive concept is not limited thereto. A short may occur also between the first bump S1-1 and the second bump S1-2 of the first output bump S1. In this case, in the first output bump S1, the first bump S1-1 may not output the first data signal DSG1, and the second bump S1-2 may output the first data signal DSG1, and thus the first bump S1-1 and the second bump S1-2 may be individually driven.

As the first bump S1-1 and the second bump S1-2 of the first output bump S1 are individually driven, a switching element of each of the first bump S1-1 and the second bump S1-2 may be individually turned off when a vertical line defect occurs. Accordingly, it may be possible to more accurately identify positions of the bumps or pads around which shorts occur while performing a defect analysis.

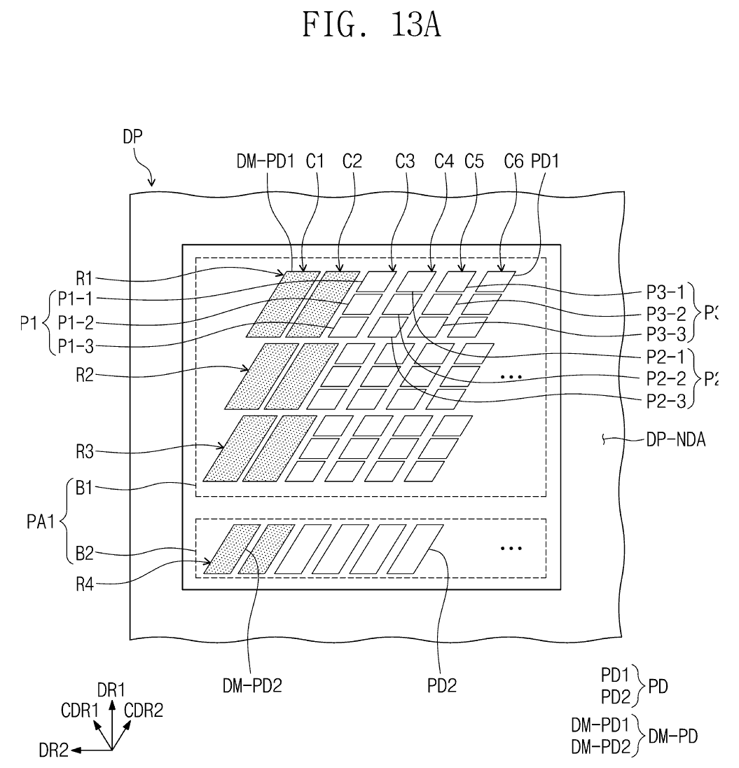

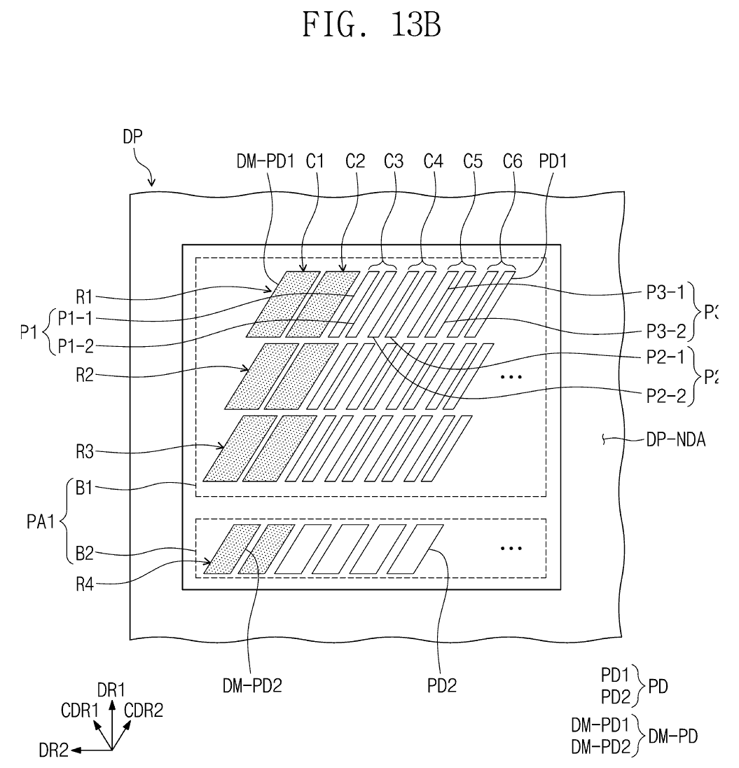

FIGS. 13A and 13B respectively are plan views of first pad regions of display panels according to other embodiments of the inventive concept. Detailed descriptions of the same components as those described with reference to FIG. 9B will be omitted.

Referring to FIG. 13A, a first output pad P1 disposed in a first region B1 may further include a third pad P1-3 which is spaced apart from a first pad P1-1 and a second pad P1-2 in the first direction DR1. The third pad P1-3, and the first pad P1-1 and the second pad P1-2 may transmit the same first data signal DSG1 (see FIG. 10) to the same signal line.

According to an embodiment of the inventive concept, the length of each of the first pad P1-1, the second pad P1-2, and the third pad P1-3 in the second oblique direction CDR2 may be smaller than the length of a first output dummy pad DM-PD1 in the second oblique direction CDR2. That is, as the first output pad P1 is divided, the length of each of the first pad P1-1, the second pad P1-2, and the third pad P1-3 in the second oblique direction CDR2 may be smaller than the length of the first output dummy pad DM-PD1 which is not divided in the second oblique direction CDR2. Although the description is made on the basis of the second oblique direction CDR2, it may be similarly applied to the length in the first direction DR1.

In an embodiment, on a plane, the length of the dummy pad DM-PD1 in the second oblique direction CDR2 may be greater than the sum of the length of the first pad P1-1 in the second oblique direction CDR2, the length of the second pad P1-2 in the second oblique direction CDR2, and the length of the third pad P1-3 in the second oblique direction CDR2.

Referring to FIG. 13B, the output pads PD1 may each include pads which are divided and are spaced apart from each other in the second direction DR2. For example, the first output pad P1 may include the first pad P1-1 and the second pad P1-2 spaced apart from the first pad P1-1 in the second direction DR2. The first pad P1-1 and the second pad P1-2 may receive the same data signal output from the corresponding bumps.

According to an embodiment of the inventive concept, on a plane, a length in the second direction DR2 may mean a width or a lateral dimension of the pad. The width of each of the first pad P1-1 and the second pad P1-2 may be smaller than the width of the dummy pad DM-PD. On the plane, the width of the dummy pad DM-PD may be greater than the sum of the widths of the first pad P1-1 and the second pad P1-2.

In an embodiment, on a plane, the area of the first pad P1-1 may be smaller than the area of the dummy pad DM-PD, and the area of the second pad P1-2 may also be smaller than the area of the dummy pad DM-PD. Similarly, the description of comparing the shapes of the dummy bumps corresponding to the dummy pads DM-PD described above may also be applied to the first bump corresponding to the first pad P1-1 and the second bump corresponding to the second pad P1-2.

According to an embodiment of the inventive concept, a signal pad includes a first pad and a second pad spaced apart from the first pad, which transmit the same data signal to the same signal line. When a short occurs in a region adjacent to a first bump and a second bump respectively corresponding to the first pad and the second pad, the first bump and the second bump may be individually driven. Even though the first bump is not electrically connected to the first pad due to an occurrence of open circuit, the second bump may be electrically connected to the second pad, and thus the data signal may be transmitted to a display panel via the second pad. Accordingly, a vertical line defect that a stain or a dark spot is visible in a vertical direction on a display region, may be reduced.

When electronic components are bonded, a short may occur due to an aggregation of conductive balls in a conductive adhesive layer. Since the first bump and the second bump spaced apart from the first bump, which output the same data signal on the same signal line, are individually driven, it may be possible to accurately identify a position at which the short caused by aggregating the conductive balls occurs. Accordingly, the position of an initial short defect may be easily detected, and thus it is possible to quickly and accurately determine a cause of the defect.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. An electronic device comprising:
a display panel;
an electronic component electrically connected to the display panel; and
a conductive adhesive layer electrically connecting the display panel and the electronic component,
wherein the display panel includes a pixel, a signal line electrically connected to the pixel, and a signal pad electrically connected to the signal line,
wherein the signal pad includes a first pad, and a second pad spaced apart from the first pad, and
wherein the first pad and the second pad transmit the data signal to a same signal line.

2. The electronic device of claim 1, wherein the electronic component comprises a driver chip package, and
the driver chip package includes an input bump configured to receive a first signal from the outside, and an output bump configured to provide a second signal generated according to the first signal.

3. The electronic device of claim 2, wherein the output bump comprises:
a first bump electrically connected to the first pad; and
a second bump electrically connected to the second pad.

4. The electronic device of claim 3, wherein the driver chip package further comprises a driver chip including a first output terminal and a package substrate, and
wherein the first output terminal provides the second signal to the first bump and the second bump.

5. The electronic device of claim 3, wherein the driver chip package further comprises a driver chip including a first output terminal and a package substrate, and
wherein the package substrate includes a first switching element configured to control the second signal of the first bump, and a second switching element configured to control the second signal of the second bump.

6. The electronic device of claim 5, wherein the conductive adhesive layer comprises an adhesive layer and a plurality of conductive balls disposed in the adhesive layer, and
wherein, when some of the plurality of conductive balls electrically connect the first bump and the second bump, the first switching element or the second switching element is turned off.

7. The electronic device of claim 3, wherein the output bump is provided in plurality,
wherein the plurality of output bumps comprise a first output bump and a second output bump, and
wherein the first output bump outputs a first data signal and the second output bump outputs a second data signal.

8. The electronic device of claim 7, wherein the conductive adhesive layer comprises an adhesive layer and a plurality of conductive balls disposed in the adhesive layer, and
wherein, when some of the plurality of conductive balls electrically connect the first bump of the first output bump and the first bump of the second output bump, the first bump of the first output bump does not output the first data signal, and the first bump of the second output bump outputs the second data signal.

9. The electronic device of claim 1, wherein the signal pad is provided in plurality,
wherein the plurality of signal pads comprise a first signal pad and a second signal pad,
wherein the first signal pad and the second signal pad are disposed in a same row, and
wherein the first signal pad receives a first data signal and the second signal pad receives a second data signal.

10. The electronic device of claim 9, wherein the conductive adhesive layer comprises an adhesive layer and a plurality of conductive balls disposed in the adhesive layer, and
wherein, when some of the plurality of conductive balls electrically connect the first pad of the first signal pad and the first pad of the second signal pad, the first pad of the first signal pad does not receive the first data signal and the first pad of the second signal pad receives the second data signal.

11. The electronic device of claim 1, wherein the first pad and the second pad respectively comprise a first conductive pattern electrically connected to a terminal portion of the signal line and a second conductive pattern disposed on the first conductive pattern.

12. The electronic device of claim 1, wherein the signal pad extends in a first direction,
wherein the display panel further comprises a dummy pad spaced apart from the signal pad in a second direction crossing the first direction,
wherein a length of the first pad in the first direction is smaller than a length of the dummy pad in the first direction, and
wherein a length of the second pad in the first direction is smaller than a length of the dummy pad in the first direction.

13. The electronic device of claim 1, wherein the signal pad extends in a first direction,
wherein the display panel further comprises a dummy pad spaced apart from the signal pad in a second direction crossing the first direction,
wherein a length of the first pad in the second direction is smaller than a length of the dummy pad in the second direction, and
wherein a length of the second pad in the second direction is smaller than a length of the dummy pad in the second direction.

14. The electronic device of claim 1, wherein the signal pad further comprises a third pad which is spaced apart from the first pad and the second pad, and
wherein the first pad, the second pad and the third pad transmit the same data signal to the same signal line.

15. An electronic device comprising:
a first electronic component including an input pad and an output pad spaced apart from the input pad;
a second electronic component including an input bump configured to receive a first signal from the input pad, and an output bump configured to provide a second signal generated from the output pad according to the first signal; and
a conductive adhesive layer electrically connecting the first electronic component and the second electronic component,
wherein the output bump includes a first bump and a second bump spaced apart from the first bump, and
wherein the first bump and the second bump output the same data signal to the first electronic component.

16. The electronic device of claim 15, wherein the output pad comprises:
a first pad electrically connected to the first bump; and
a second pad electrically connected to the second bump.

17. The electronic device of claim 15, wherein the second electronic component further comprises a driver chip including a first output terminal and a package substrate, and
wherein the first output terminal provides the second signal to the first bump and the second bump.

18. The electronic device of claim 17, wherein the package substrate comprises:
a first switching element configured to control the second signal of the first bump; and
a second switching element configured to control the second signal of the second bump.

19. The electronic device of claim 18, wherein the conductive adhesive layer comprises an adhesive layer and a plurality of conductive balls disposed in the adhesive layer, and
wherein, when some of the plurality of conductive balls electrically connect the first bump and the second bump, the first switching element or the second switching element is turned off.

20. The electronic device of claim 15, wherein the second electronic component further comprises a dummy bump spaced apart from the output bump,
wherein an area of the first bump is smaller than an area of the dummy bump, and
wherein an area of the second bump is smaller than an area of the dummy bump.
